(19) United States
(12) Patent Application Publication
(10) Pub. No.: US 2011/0229638 A1
(43) Pub. Date: Sep. 22, 2011

(54) SYSTEM AND METHOD FOR POLYCRYSTALLINE SILICON DEPOSITION

(75) Inventor: Wenjun QIN, Missoula, MT (US)

(73) Assignee: GT SOLAR INCORPORATED, Merrimack, NH (US)

(21) Appl. No.: 13/051,152

(22) Filed: Mar. 18, 2011

Related U.S. Application Data
(60) Provisional application No. 61/315,469, filed on Mar. 19, 2010.

(51) Int. Cl. C23C 16/24; C23C 16/455; C23C 16/52

(52) U.S. Cl. 427/255.28; 118/715

(57) ABSTRACT

A method for making polycrystalline silicon from a gas comprising at least one silicon precursor compound is disclosed. The method can be effected from a gas comprising a polycrystalline silicon precursor compound in a chemical vapor deposition system by establishing a first flow pattern of the gas in a chemical vapor deposition reaction chamber, promoting reaction of at least a portion of the at least one precursor compound from the gas having the first flow pattern into polycrystalline silicon, establishing a second flow pattern of the gas in the reaction chamber, and promoting reaction of at least a portion of the at least one precursor compound from the gas having the second flow pattern into polycrystalline silicon. The chemical vapor deposition system can comprise a gas source comprising a gas with at least one precursor compound; a reaction chamber at least partially defined by a base plate and a bell jar; a first nozzle group disposed in one of the base plate and the bell jar, the first nozzle group fluidly connected to the gas source through a first manifold and a first flow regulator; a second nozzle group including a plurality of nozzles disposed in one of the base plate and the bell jar, the plurality of nozzles fluidly connected to the gas source through a second manifold and a second flow regulator.

### CROSS-REFERENCE TO RELATED APPLICATION

This application claims the benefit under 35 U.S.C. §119 of U.S. Patent Application No. 61/315,469, filed Mar. 19, 2010, titled SYSTEM AND METHOD FOR POLYCRYSTALLINE SILICON DEPOSITION, which is incorporated herein by reference in its entirety for all purposes.

### BACKGROUND OF THE INVENTION

1. Field of the Invention

The present invention relates to systems and methods of polycrystalline silicon deposition and in particular to systems and methods of polycrystalline silicon deposition with staged feeding operations involving a plurality of feed nozzles during, for example, chemical vapor deposition (CVD) processes.

2. Discussion of Related Art

Schweickert et al., in U.S. Pat. No. 3,011,877, disclose the production of high-purity semiconductor materials for electrical purposes.

Bischoff, in U.S. Pat. No. 3,146,123, discloses a method for producing pure silicon.

Sandmann et al., in U.S. Pat. No. 3,286,685, disclose a process and apparatus for pyrolytic production of pure semiconductor material, preferably silicon.

Yatsurugi et al., in U.S. Pat. No. 4,147,814, disclose a method of manufacturing high-purity silicon rods having a uniform sectional shape.

Garavaglia et al., in U.S. Pat. No. 4,309,241, disclose gas curtain continuous chemical vapor deposition production of semiconductor bodies.

Rogers et al., in U.S. Pat. No. 4,681,652, disclose the manufacture of polycrystalline silicon.

Nagai et al., in U.S. Pat. No. 5,382,419, disclose the production of high-purity polycrystalline silicon rod for semiconductor applications.

Keck et al., in U.S. Pat. No. 5,545,387, disclose the production of high-purity polycrystalline silicon rod for semiconductor applications.

Chandra et al., in U.S. Pat. No. 6,365,225 B1, disclose a cold wall reactor and method for chemical vapor deposition of bulk polysilicon.

Chandra et al., in U.S. Pat. No. 6,284,312 B1, disclose a method and apparatus for chemical vapor deposition of polysilicon.

Tao et al., in U.S. Pat. No. 6,590,344 B2, disclose selectively controllable gas feed zones for a plasma reactor.

Basceri et al., in U.S. Pat. No. 6,884,296 B2, disclose reactors having gas distributors and methods for depositing materials onto micro-device workpieces.

Sandhu, in U.S. Patent Application Publication No. 2005/0189073 A1, discloses a gas delivery device for improved deposition of dielectric material.

Huang et al., in U.S. Patent Application Publication No. 2005/0241763 A1, disclose a gas distribution system having fast gas switching capabilities.

Wan et al., in U.S. Patent Application Publication No. 2007/0251455 A1, disclose increased polysilicon deposition in a CVD reactor.

### SUMMARY OF THE INVENTION

One or more aspects of the invention relate to a method for making polycrystalline silicon from a gas comprising at least one silicon precursor compound. One or more embodiments of the method for making polycrystalline silicon can comprise establishing a first flow pattern of the gas in a chemical vapor deposition reaction chamber, promoting reaction of at least a portion of the at least one precursor compound from the gas having the first flow pattern into polycrystalline silicon, establishing a second flow pattern of the gas in the reaction chamber, and promoting reaction of at least a portion of the at least one precursor compound from the gas having the second flow pattern into polycrystalline silicon. In some cases thereof, establishing the first flow pattern comprise introducing the gas into the reaction chamber through a first nozzle group consisting of, for example, a single nozzle. In further cases, establishing the first flow pattern can comprise introducing the gas into the reaction chamber through a first nozzle group and establishing the second flow pattern of the gas in the reaction chamber can comprise introducing the gas through a second nozzle group. In still further cases, establishing the second flow pattern of the gas in the reaction chamber can comprise discontinuing the introduction of the gas through the first nozzle group. In other further cases, the method for making polycrystalline silicon can further comprise establishing a third flow pattern of the gas in the reaction chamber. In yet further cases thereof, establishing the third flow pattern of the gas in the reaction chamber can comprise discontinuing the introduction of the gas through the first nozzle group. In other cases, establishing the third flow pattern of the gas in the reaction chamber can comprise discontinuing the introduction of the gas through the second nozzle group.

In accordance with further embodiments of the invention, the method for making polycrystalline silicon can be effected from a gas comprising a polycrystalline silicon precursor compound in a chemical vapor deposition system. The method for making polycrystalline silicon can comprise introducing at least a portion of the gas comprising the polycrystalline silicon precursor compound into a reaction chamber of the chemical vapor deposition system through a first nozzle group, promoting conversion of at least a portion of the precursor compound into polycrystalline silicon from the at least a portion of the gas introduced into the reaction chamber through the first nozzle group, introducing at least a portion of the gas into the reaction chamber through a second nozzle group, and promoting conversion of at least a portion of the precursor compound into polycrystalline silicon from the at least a portion of the gas introduced into the reaction chamber through the second nozzle group. The first nozzle group can consist of a single nozzle. The method can further comprise introducing at least a portion of the gas into the reaction chamber through a third nozzle group and, in some cases, can also further comprise promoting conversion of at least a portion of the precursor compound into polycrystalline silicon from the at least a portion of the gas introduced into the reaction chamber through the third nozzle group. The method also can further comprise regulating a flow rate of gas introduced through any of the first nozzle group, the second nozzle group, and the third nozzle group. The method can also further comprise discontinuing the introduction of the at least a portion of the gas introduced through the second nozzle group. The method for making the polycrystalline silicon can further comprise discontinuing the introduction of the at least a portion of the gas introduced through the first nozzle group. The method can further comprise introducing at least a portion of the gas into the reaction chamber through a fourth nozzle group and, in some cases, can also further comprise promoting conversion of at least a portion of the precursor compound into polycrystalline silicon from the at least a portion of the gas introduced into the reaction chamber through the fourth nozzle group.

One or more aspects of the invention relate to a chemical vapor deposition system. The chemical vapor deposition system can comprise a gas source comprising a gas with at least one precursor compound, such as trichlorosilane; a reaction chamber at least partially defined by a base plate and a bell jar; a first nozzle group disposed in one of the base plate and the bell jar, the first nozzle group fluidly connected to the gas source through a first manifold and a first flow regulator; a second nozzle group including a plurality of nozzles disposed in one of the base plate and the bell jar, the plurality of nozzles fluidly connected to the gas source through a second manifold and a second flow regulator; and a controller configured to regulate flow of gas from the gas source through the first nozzle group and flow of gas from the gas source through the second nozzle group. The chemical vapor deposition system can further comprise a third nozzle group including a plurality of nozzles disposed in one of the base plate and the bell jar, the plurality of nozzles of the third nozzle group fluidly connected to the gas source through a third manifold and a third flow regulator. In some cases, the controller can be further configured to regulate flow of the gas from the gas source through the third nozzle group. The first nozzle group can consist of a single nozzle, the second nozzle group can consist of three nozzles, and the third nozzle group can consist of six nozzles. In some configurations of the chemical vapor deposition system, the first nozzle group consists of a single nozzle and the second nozzle group consists of three nozzles.

### BRIEF DESCRIPTION OF THE DRAWINGS

The accompanying drawings are not drawn to scale. In the drawings, each identical or nearly identical component that is illustrated in various figures is represented by a like numeral. For purposes of clarity, not every component may be labeled in every drawing.

In the drawings:

FIG. 1 is a schematic illustration of a portion of a deposition system in which one or more aspects of the invention may be practiced;

FIG. 2 is another schematic illustration of a portion of a vapor deposition system in which one or more aspects of the invention may be practiced;

FIG. 3 is a graph showing a simulated growth of a polycrystalline silicon rod with increasing feed rate into a reaction chamber as discussed in the Example, in accordance with one or more embodiments of the invention; and

FIG. 4 is a graph showing three feed stages for a simulated polycrystalline silicon deposition process as discussed in the Example, in accordance with one or more embodiments of the invention.

### DETAILED DESCRIPTION

One or more aspects of the invention relate to deposition processes that provide a controlled or regulated level of gas velocity in a deposition reaction chamber. Some aspects of the invention relate to providing a maximum gas velocity in a reaction chamber even with an increasing flow rate of a feed stream introduced into the reaction chamber. Further aspects of the invention can provide reducing convective heat loss associated with increasing gas velocity in a deposition reaction chamber, even with increasing mass flow rates of a feed stream introduced into the reaction chamber. Still further aspects of the invention can relate to two phase processes having controlled levels or conditions that reduce unnecessary or undesirable heat transfer or loss from a reaction surface while providing sufficient flow conditions in a bulk fluid that reduces or even eliminates any concentration gradients from the surface to the bulk fluid.

One or more aspects of the invention relate to a method for making polycrystalline silicon from a gas comprising at least one silicon precursor compound. In some cases, the method for making polycrystalline silicon can be effected from a gas comprising a polycrystalline silicon precursor compound in a chemical vapor deposition system or apparatus. One or more embodiments of the method can comprise establishing a first flow pattern of the gas in a chemical vapor deposition reaction chamber, promoting reaction of at least a portion of the at least one precursor compound from the gas having the first flow pattern into polycrystalline silicon, establishing a second flow pattern of the gas in the reaction chamber, and promoting reaction of at least a portion of the at least one precursor compound from the gas having the second flow pattern into polycrystalline silicon. The method can comprise introducing at least a portion of the gas comprising the polycrystalline silicon precursor compound into a reaction chamber of the chemical vapor deposition system through a first nozzle group, promoting conversion of at least a portion of the precursor compound into polycrystalline silicon from the at least a portion of the gas introduced into the reaction chamber through the first nozzle group, introducing at least a portion of the gas into the reaction chamber through a second nozzle group, and promoting conversion of at least a portion of the precursor compound into polycrystalline silicon from the at least a portion of the gas introduced into the reaction chamber through the second nozzle group. One or more methods of the invention can involve embodiments wherein establishing the first flow pattern comprises introducing the gas into the reaction chamber through a first nozzle group consisting of, for example, a single nozzle. One or more methods of the invention can involve further embodiments wherein establishing the first flow pattern comprises introducing the gas into the reaction chamber through a first nozzle group and establishing the second flow pattern of the gas in the reaction chamber comprises introducing the gas through a second nozzle group. In still further embodiments of the invention, establishing the second flow pattern of the gas in the reaction chamber comprises discontinuing the introduction of the gas through the first nozzle group. In other further embodiments of the invention, the method for making polycrystalline silicon can further comprise establishing a third flow pattern of the gas in the reaction chamber. In yet further embodiments of the invention, establishing the third flow pattern of the gas in the reaction chamber comprises discontinuing the introduction of the gas through the first nozzle group. In other cases, establishing the third flow pattern of the gas in the reaction chamber comprises discontinuing the introduction of the gas through the second nozzle group. In some configurations in accordance with some embodiments of the invention, the first nozzle group can consist of a single nozzle. The method can, in accordance with further aspects of the invention, further comprise introducing at least a portion of the gas into the reaction chamber through a third nozzle group. The method also can further comprise, in accordance with still further aspects of the invention, regulating a flow rate of gas introduced through any of the first nozzle group, the second nozzle group, and the third nozzle group. The method can, in accordance with even further aspects of the invention, also comprise discontinuing the introduction of the at least a portion of the gas introduced through the second nozzle group. The method for making the polycrystalline silicon can, in accordance with yet further aspects of the invention, comprise discontinuing the introduction of the at least a portion of the gas introduced through the first nozzle group. The method can comprise, in accordance with other further aspects of the invention, introducing at least a portion of the gas into the reaction chamber through a fourth nozzle group.

One or more aspects of the invention can also relate to a chemical vapor deposition system. In one or more configurations in accordance with some aspects of the invention, the chemical vapor deposition system can comprise a gas source comprising a gas with at least one precursor compound; a reaction chamber at least partially defined by a base plate and a bell jar; a first nozzle group disposed in one of the base plate and the bell jar, the first nozzle group fluidly connected to the gas source through a first manifold and a first flow regulator; a second nozzle group including a plurality of nozzles disposed in one of the base plate and the bell jar, the plurality of nozzles fluidly connected to the gas source through a second manifold and a second flow regulator; and a controller configured to regulate flow of gas from the gas source through the first nozzle group and flow of gas from the gas source through the second nozzle group. The chemical vapor deposition system can further comprise a third nozzle group including a plurality of nozzles disposed in one of the base plate and the bell jar, the plurality of nozzles of the third nozzle group fluidly connected to the gas source through a third manifold and a third flow regulator. In some cases, the controller is further configured to regulate flow of the gas from the gas source through the third nozzle group. The first nozzle group can consist or consist essentially of a single nozzle, the second nozzle group can consist or consist essentially of three nozzles, and the third nozzle group can consist or consist essentially of six nozzles. In some configurations of the chemical vapor deposition system, the first nozzle group consists or consists essentially of a single nozzle and the second nozzle group consists or consists essentially of three nozzles.

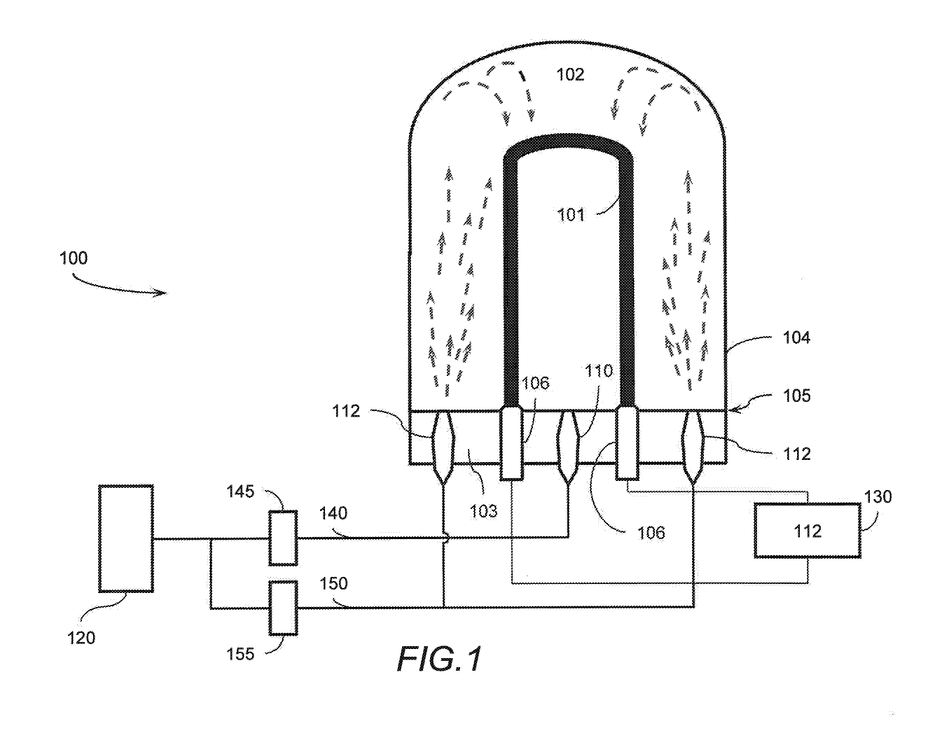

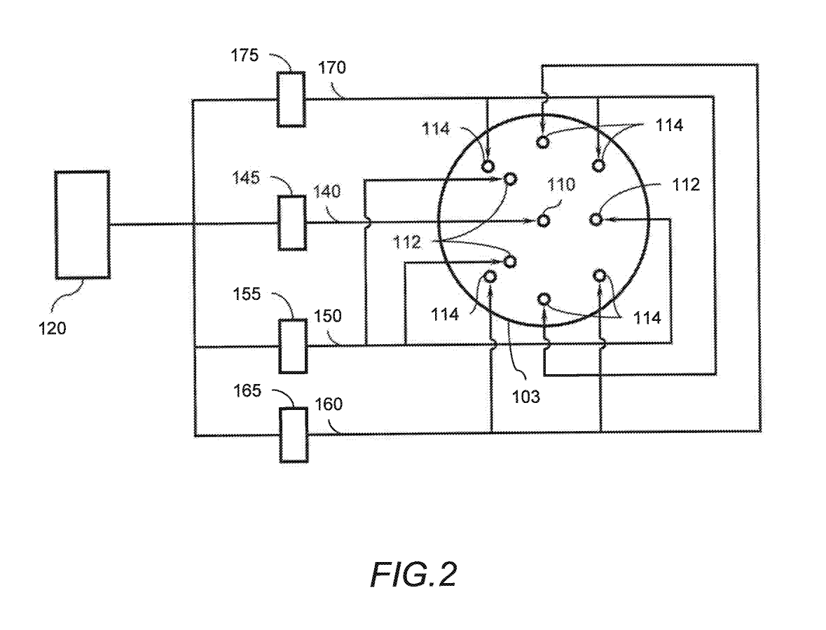

FIGS. 1 and 2 schematically illustrate a chemical vapor deposition system 100 in accordance with one or more aspects of the present invention for making or producing a semiconductor material, such as a polycrystalline silicon rod 101. Deposition system 100 typically comprises a reaction chamber 102 enclosed and defined, at least partially, by a base structure or base plate 103 and a housing or a bell jar 104. An interface 105 between bell jar 104 and base plate 103 is sealed to be gas-tight. In typical configurations of some aspects of the invention, base plate 103 and bell jar 104 have corresponding dimensions and have circular cross-sections so that the interface circumferentially partially defines reaction chamber 102.

At least one but preferably a plurality of rods 101 are simultaneously grown in reaction chamber 102, with each of the at least one rod secured to holders 106. Further, each of holders 106 is typically disposed in or secured to base plate 103. Typically, filaments are utilized as initial deposition structures upon which the desired material grows.

Each of the one or more rods 101 is typically heated to promote one or more reactions thereon and promote growth and deposition of the desired material from one or more precursor compounds supplied into reaction chamber 102. For example, each of rods 101 can be electrically heated by a heating current supplied thereto by one or more electrical sources 130 through holders 106. The particular temperature or range of temperatures utilized during the deposition process may depend on several considerations including, for example, the desired or deposited material, one or more characteristics of the material, the rate of growth of the material, the rate of heat loss or transfer from the reaction chamber, and, in some cases, one or more characteristics of the gas in the reaction chamber such as the type and relative or stoichiometric amounts of the one or more precursor compounds. For example, temperatures in a range of from about 900° C. to about 1,500° C., preferably in a range of from about 900° C. to about 1,100° C., may be implemented in any of the various production processes of the invention that involve silicon deposition.

The one or more precursor compounds can be introduced into reaction chamber 102 as a component of a gas through at least one nozzle. For example, when silicon is to be produced in chemical vapor deposition system 100, one or more silicon precursor compounds can be introduced into reaction chamber 102. Non-limiting examples of precursor compounds that can be utilized to implement one or more aspects of the present invention for vapor deposition of, for example, polycrystalline silicon, include silanes (SiₙH₂ₙ₊₂) such as SiH₄, chlorosilanes such as silicon tetrachloride, dichlorosilane, and trichlorosilane, and hydrogen. Inert compounds or components that do not participate in any of the deposition reactions may also be introduced into the reaction chamber to facilitate, modify, or adjust any of the conditions of any of the deposition process. In accordance with further aspects of the invention, such as those directed to vapor deposition of other materials, corresponding halogenated compounds can be utilized as the one or more precursor compounds. For example, germanium tetrachloride can be utilized with hydrogen as a carrier and reducing species during deposition reactions therefor. Further aspects of the invention can involve utilizing monomethyltrichlorosilane, optionally with one or more hydrocarbon compounds, as an at least one precursor compound for deposition of silicon carbide.

Deposition system 100 typically further includes at least one nozzle disposed to introduce one or more precursor compounds into reaction chamber 102. In accordance with one or more particular configurations of the invention, deposition system 100 includes a first nozzle group with at least one nozzle 110 disposed, at least partially, in base plate 103. However, one or all of the at least one nozzle 110 can be at least partially disposed in bell jar 104. As exemplarily illustrated, the first nozzle group can consist or consist essentially of a single nozzle disposed centrally in base plate 103. In configurations wherein the first nozzle group has a plurality of nozzles, each of the nozzles is preferably spatially separated equidistantly from an adjacent nozzle. In some further configurations, the first nozzle group has a plurality of nozzles, each of the nozzles is spatially separated equidistantly from an adjacent nozzle and also spatially separated equidistantly from the center of base plate 103.

In accordance with further aspects of the invention, deposition system 100 typically further comprises a second nozzle group including at least one, preferably a plurality of spatially separated nozzles 112. As with the first nozzle group, at least one, and optionally each of nozzles 112 of the second nozzle group is at least partially disposed in base plate 103. Further aspects of the invention can involve configurations of deposition systems wherein at least one of nozzles 112 of the second nozzle group is at least partially disposed in bell jar 104. Still further aspects of the invention can involve configurations of deposition systems wherein at least one of nozzles 112 of the second nozzle group is at least partially disposed in base plate 103 and at least one of nozzles 112 of the second nozzle group is at least partially disposed in bell jar 104. In configurations wherein the second nozzle group has a plurality of nozzles, each of the nozzles is preferably spatially separated equidistantly from an adjacent nozzle. In some further configurations, the second nozzle group has a plurality of nozzles, wherein each of the nozzles is spatially separated equidistantly from an adjacent nozzle and also spatially separated equidistantly from the center of base plate 103. As exemplarily illustrated, the second nozzle group can consist or consist essentially of three nozzles that are equispatially disposed in base plate 103. For example, each of nozzles 112 can be equidistantly separated from an adjacent nozzle at an equivalent radial distance from a center of base plate 103. In another non-limiting configuration, each of the nozzles in the second nozzle group can be at least partially disposed in bell jar 104 at a position that is equispatially separated from adjacent nozzles 112.

In accordance with further aspects of the invention, deposition system 100 further comprises a third nozzle group including at least one, preferably a plurality of equispatially-separated nozzles 114. As with the first nozzle group and the second nozzle group, at least one of nozzles 114 of the third nozzle group is at least partially disposed in base plate 103. Further aspects of the invention can involve configurations of deposition systems wherein at least one of nozzles 114 of the third nozzle group is at least partially disposed in bell jar 104. Still further aspects of the invention can involve configurations of deposition systems wherein at least one of nozzles 114 of the third nozzle group is at least partially disposed in base plate 103 and at least one of nozzles 114 of the third nozzle group is at least partially disposed in bell jar 104. In configurations wherein the third nozzle group has a plurality of nozzles, each of the nozzles is preferably spatially separated equidistantly from an adjacent nozzle. In some further configurations, the third nozzle group has a plurality of nozzles, wherein each of the nozzles is spatially separated equidistantly from an adjacent nozzle and also spatially separated equidistantly from the center of base plate 103. As also exemplarily illustrated, the third nozzle group can consist or consist essentially of six nozzles that are equispatially disposed in base plate 103, but optionally at a different radial dimension as that defined by the second nozzle group.

In one or more various configurations and embodiments of the invention, the at least one nozzle of any of the nozzle groups is preferably at least partially within base plate 103 or bell jar 104 such that a fluid exit end of the one or more nozzles does not protrude into chamber 102, or beyond a plane or surface of base plate 103 or bell jar 104.

At least one but preferably each of the nozzles, base plate 103, and bell jar 104 are typically cooled by a coolant fluid from a cooling system (not shown) to prevent or at least inhibit deposition and growth of the material thereon during deposition operations. The cooling system typically comprises a chiller that reduces the temperature of the coolant.

Deposition system 100 typically further comprises at least one source 120 of the one or more precursor compounds to be introduced into reaction chamber 102. Deposition system 100 preferably further comprises at least one manifold for each of the groupings of nozzles utilized to regulate introduction of the one or more precursor compounds into reaction chamber 102 from the at least one source 120. Further, deposition system 100 preferably also comprises one or more flow control devices that can regulate a flow rate of the one or more precursor compounds introduced into reaction chamber through any one of the at least one nozzle by way of the at least one manifold.

For example, deposition system 100 can comprise a first manifold 140 fluidly connecting the at least one source 120 with the at least one precursor compound to the first nozzle group with the at least one nozzle 110 through a first at least one flow regulator 145. Deposition system 100 can also comprise a second manifold 150 fluidly connecting the at least one source 120 with the at least one precursor compound to the second nozzle group with the at least one nozzle 112 through a second at least one flow regulator 155. Deposition system 100 can also further comprise a third manifold 160 fluidly connecting the third nozzle group with the at least one nozzle 114 to the at least one source 120 through a third at least one flow regulator 165. As exemplarily illustrated in FIG. 2, some configurations of deposition system 100 can involve a fourth manifold 170 fluidly connecting the at least one source 120 with the at least one precursor compound to at least one of nozzles 114 of the third nozzle group through a fourth at least one flow regulator 175.

In other instances, however, the deposition system can comprise a fourth nozzle group including a plurality of nozzles wherein at least one of the plurality of nozzles is disposed in any of one or both the base plate and the bell jar. In such configurations, the deposition system typically further comprises a fourth manifold fluidly connecting the at least one nozzle of the fourth nozzle group to the at least one source of at least one precursor compound through at least one flow regulator.

Other configurations of the present invention can involve a nozzle serving in one or more nozzle groups. For example, nozzle 110, exemplarily illustrated as being positioned at a center of base plate 103 can be involved in introducing gas with the at least one precursor compound into reaction chamber 102 as part of the first nozzle group collective and also as a part of the second nozzle group collective.

In embodiments of the invention involving two or more precursor compounds, a mixture of the precursor compounds can be introduced into the reaction chamber as a mixture thereof through any of the nozzle groups. In other variants thereof, the two or more precursor compounds can be introduced separately or in combinations through any of the nozzle groups. In still other variants, the two or more precursor compounds can be introduced into the reaction chamber with one or more inert compounds, typically as gases and as a component of the mixture. In other cases, the one or more inert gases can be separately or collectively introduced into the reaction chamber through one or more nozzles of any of the nozzle groups.

A variety of nozzle sizes may be involved in implementing the various aspects of the invention. For example, the first nozzle group can utilize nozzles with a diameter of from about 20 mm to about 30 mm, with a preferred diameter of about 20 mm. In another exemplary configuration, the second nozzle group can utilize nozzles with a diameter of from about 20 mm to about 40 mm, with a preferred diameter of about 30 mm. In another exemplary configuration, the third nozzle group can utilize nozzles with a diameter of from about 20 mm to about 50 mm, with a preferred diameter of about 30 mm. The size of any of the nozzles in any of the nozzle groups may depend on several factors including, but not limited to, the characteristics of the gas introduced therethrough into the reaction chamber, such as the gas density, temperature, pressure, and volumetric or mass flow rate. Typically, one of the considerations involves selecting a nozzle size that provides a desired average flow velocity in the reaction chamber. Further configurations can involve utilizing a nozzle or a plurality of nozzles in any of the nozzle groups having an adjustable or variable discharge aperture.

A variety of flow regulators may be involved in implementing one or more aspects of the invention. Flow regulators can, for example, comprise one or more flow measurement elements and one or more valves along any of the flow paths from, for example, the one or more sources to any of the nozzle groups. In some configurations of the invention, the deposition system can further comprise one or more controllers configured to regulate flow through any of the flow paths to any of the nozzle groups. For example, the one or more controllers (not shown) can be operatively coupled to one or more valves or flow regulators 145 to regulate a flow condition in first manifold 140, such as a flow rate of one or more precursor compounds to be introduced into reaction chamber 102 through a first nozzle group. In still further configurations, the one or more controllers can be operatively coupled to one or more valves or flow regulators 155 to regulate a flow condition in second manifold 150, such as a flow rate of one or more precursor compounds to be introduced into reaction chamber 102 through a second nozzle group. In yet further configurations, the one or more controllers can be operatively coupled to one or more valves or flow regulators 165 to regulate a flow condition in third manifold 160, such as a flow rate of one or more precursor compounds to be introduced into reaction chamber 102 through a third nozzle group. In even further configurations, the one or more controllers can be operatively coupled to one or more valves or flow regulators 175 to regulate a flow condition in fourth manifold 170, such as a flow rate of one or more precursor compounds to be introduced into reaction chamber 102 through a third or a fourth nozzle group.

The flow condition can be a volumetric or a mass flow rate of the gas comprising the one or more precursor compounds. In other configurations, the flow condition can be a mass fraction or a volumetric fraction of at least one precursor compound to be introduced into the reaction chamber.

The one or more flow measurement elements can comprise any suitable device that provides a value of a characteristic or property of the gas flowing therethrough. For example, the flow measurement element can utilize a pressure differential across a restriction to provide an indication of a flow rate of the gas.

The controller may be implemented using one or more computer systems, which may be, for example, a general-purpose computer or a specialized computer system. Non-limiting examples of control systems that can be utilized or implemented to effect one or more processes of the systems or subsystems of the invention include distributed control systems, such as the DELTA V digital automation system from Emerson Electric Co., and programmable logic controllers, such as those available from Allen-Bradley or Rockwell Automation, Milwaukee, Wis. Typically, the controller utilizes a control algorithm that manipulates or utilizes one or more input parameters to generate one or more output signals. For example, the algorithm can involve a control loop utilizing an input value such as measured parameter, e.g., a flow rate as determined by any of the flow measurement devices, and compares the measured parameter to a set point, which can be manually defined as a predetermined parameter, to generate the output signal that can drive or actuate the valve which regulates flow rate. The controller can also comprise one or more overlaying algorithms that can automatically adjust one or more operating conditions of the deposition system. For example, the controller can also comprise cascading algorithms with a deposition sub-algorithm that defines or regulates the rate of introduction of the gas into the reaction chamber as a function of time, which can be utilized, for example, to generate a flow set point, an array of time-dependent flow set points, or a schedule of deposition parameters, any of which can be utilized in a flow control sub-algorithm. Other parameters that may be controlled by the controller include, for example, the temperature of the rod, or a plurality of rod temperature set points. Still other conditions that may be controlled by the controller include the sequencing of flow regulators or feed staging of the gas comprising the one or more precursor compounds to be introduced into the reaction chamber. Any of such algorithms can involve feedback control techniques with proportional, derivative, integral, or combinations of any of such gain functions.

In accordance with one or more aspects of the invention, the one or more precursor compounds, typically as a gas or with a carrier fluid, from the one or more sources can be introduced into the reaction chamber to create a first flow pattern therein. In accordance with one or more such aspects, the gas comprising the one or more precursor compounds, for example, can be introduced into the reaction chamber through a first nozzle group including at least one nozzle 110 to create the first flow pattern.

In accordance with one or more aspects of the invention, the one or more precursor compounds, typically as a gas or with a carrier fluid, from the one or more sources can be introduced into the reaction chamber to create a second flow pattern therein. Thus, for example, the gas comprising the one or more precursor compounds can be introduced into the reaction chamber through a second nozzle group including at least one nozzle 112 to create the second flow pattern, exemplarily illustrated by the dashed arrows in FIG. 1.

In accordance with one or more aspects of the invention, the one or more precursor compounds, typically as a gas or with a carrier fluid, from the one or more sources can be introduced into the reaction chamber to create a third flow pattern therein. Thus, for example, the gas comprising the one or more precursor compounds can be introduced into the reaction chamber through a third nozzle group including at least one nozzle 114 to create the third flow pattern.

Thus, during any of the various deposition operations of the invention the first flow pattern can be established, for example, by utilizing any of the nozzle groups, including, for example, a combination of any of the first, the second, the third, and other nozzle groups. For example, some particular embodiments of the invention can involve establishing a flow pattern by utilizing a nozzle group that includes nozzle 110 and one or more of any of nozzles 112 and 114. In another non-limiting example, a nozzle group utilized to create a flow pattern or introduce gas with one or more precursor compounds in the reaction chamber can include any of nozzles 112 and 114 that are peripherally disposed on base plate 103. In still another non-limiting example, a nozzle group utilized to create a flow pattern or introduce gas with one or more precursor compounds in the reaction chamber can include any of nozzles 110, 112, and 114 that are disposed in bell jar 104.

The second flow pattern can be established by, for example, utilizing any of the nozzle groups, including, for example, a combination of any of the first, the second, the third, and other nozzle groups. In still further variants, the third flow pattern can be established, for example, by utilizing any of the nozzle groups, including, for example, a combination of any of the first, the second, the third, and other nozzle groups.

The number of nozzles in a nozzle group can vary and depend on one or more considerations including, for example, the flow rate of the gas into the reaction chamber, the rate of reaction or deposition, the concentration or relative amount of one or more of the precursor compounds in the gas, the temperature of the gas, the temperature of the rod, and a desired characteristic of the gas in the reaction chamber.

For example, the number of nozzles involved in a first deposition or reaction stage, which can involve a first nozzle group that includes at least one nozzle, can be limited to provide turbulent flow conditions or flow patterns, e.g., Reynolds number of at least 5,000 to a maximum of about 100,000, in the reaction chamber. Likewise, during a second deposition or reaction stage, which can involve a second nozzle group that includes a plurality of any of nozzles 110, 112, and 114, the number of nozzle utilized can be limited to provide turbulent flow patterns in the reaction chamber, but typically, or even preferably, at higher overall flow rates compared to the flow rate introduced during the first stage, but preferably within about the same range of Reynolds number in the reaction chamber. Further, the number of nozzles involved in a third deposition or reaction stage, which can involve a third nozzle group that includes a plurality of any of nozzles 110, 112, and 114, the number of nozzle utilized can be limited to provide turbulent flow patterns in the reaction chamber, but typically, or even preferably, at higher overall flow rates compared to the flow rate introduced during the second stage, but preferably within about the same range of Reynolds number in the reaction chamber Likewise, in embodiments of the invention that involve a fourth stage, a fourth nozzle group can include one or more of nozzles 110, 112, and 114, to create turbulent conditions, at flow rates greater than the third stage, but preferably within about the same range of Reynolds number in the reaction chamber.

Each of the stages may have respective desired ranges of average gas velocity in the reaction chamber. For example, the first stage may have a first range of average gas velocity in the reaction chamber; the second stage may have a second range of average gas velocity in the reaction chamber, the third stage may have a third range of average gas velocity in the reaction chamber. In accordance with one or more particular embodiments of the invention, the average gas velocity may be determined according to the following relationship:

$$V = k \frac{m}{{D ( N )}^{1 / 2}} ,$$

where V is the average gas velocity, k is a constant dependent on the geometric parameters of the reaction chamber, m is the mass flow rate, D is the nozzle diameter, and N is the number of nozzles.

In other cases, each of the stages may have a flow pattern in the reaction chamber with respective desired ranges of Reynolds number. For example, the first stage may have a first gas flow pattern with a first Reynolds number in a first Reynolds number range; the second stage may have a second Reynolds number in a second Reynolds number range, the third stage may have a third Reynolds number in a third Reynolds number range. Some embodiments of the invention can thus involve a first stage with a first flow pattern having an average gas velocity that implicates a maximum Reynolds number of about 5,000; about 10,000; about 20,000; about 30,000; about 50,000; or even about 100,000. Each of the other stages may have the same maximum Reynolds number. However, other embodiments of the invention may involve other stages with a maximum Reynolds number of about 10,000; about 20,000; about 30,000, about 50,000; or even about 100,000. The desired Reynolds number for any one or more of the stages may be predetermined to provide sufficient turbulent flow in the chamber to create or at least facilitate mass transfer processes that is predominantly reaction rate limited, e.g., not diffusion rate limited, while reducing or even minimizing any convective heat loss.

Reynolds number may be determined by utilizing one or more dimensions of rod 101 as a characteristic dimension. For example, the characteristic dimension can be a traveled length, L, of the fluid, e.g., the gas, along rod 101, in the following relationship:

$$Re = \frac{ρ VL}{μ} ,$$

where ρ is the density of the gas and μ is the kinematic viscosity of the gas, and V is the average flow velocity of the gas.

The gas is preferably introduced into the reaction chamber according to a predefined or predetermined schedule or recipe. For example, the gas flow rate, or the flow rate of one or more of the precursor compounds, or both, can be regulated or controlled in accordance with a first predetermined schedule while being introduced through the first nozzle group. The gas flow rate, or the flow rate of one or more of the precursor compounds, or both, can be regulated or controlled in accordance with a second predetermined schedule while being introduced through the second nozzle group. In further embodiments of the invention, the gas flow rate, or the flow rate of one or more of the precursor compounds, or both, can be regulated or controlled in accordance with a second predetermined schedule while being introduced through the third nozzle group.

The function and advantages of these and other embodiments of the invention can be further understood from the examples below, which illustrate the benefits and/or advantages of the one or more systems and techniques of the invention but do not exemplify the full scope of the invention.

### Example

This example describes a simulation of a polycrystalline silicon deposition process in accordance with one or more embodiments of the invention.

The rod surface temperature during the simulated deposition ranged from about 1,050° C. to about 990° C. The polycrystalline silicon rod diameter was simulated to grow to about 133.6 mm over a deposition period of about 79 hours. Hydrogen (H₂), dichlorosilane (H₂SiCl₂), and trichlorosilane (HSiCl₃) were utilized as the precursor compounds for the deposition simulation of polycrystalline silicon. The total mass flow rate of the precursor compounds during the simulated deposition ranged from about 346 kg/hr to about 4,110 kg/hr. The relative molar ratio of H₂:H₂SiCl₂:HSiCl₃ during the simulated deposition was about 3.7:0.1:1.

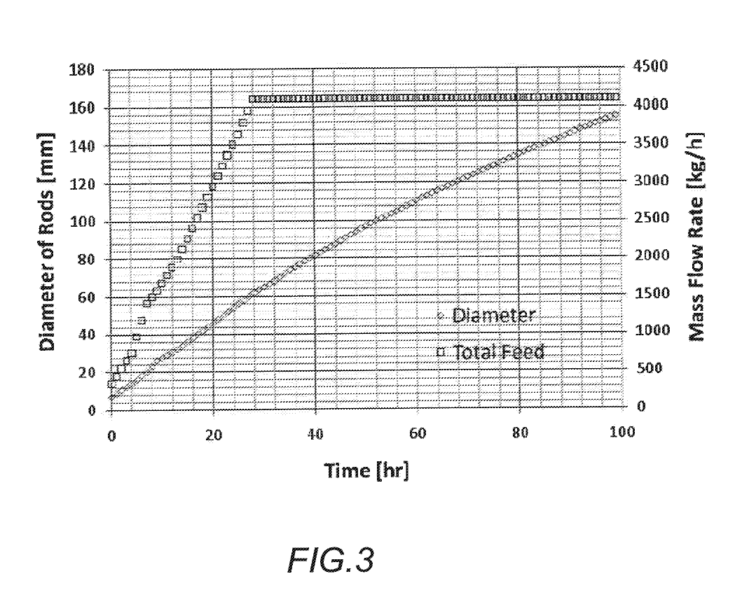

FIG. 3 is a graph showing the predicted rod diameter with increasing flow during the simulated deposition period.

The simulated deposition system was modeled as schematically illustrated in FIG. 2 with a first nozzle group including a single central nozzle 110 disposed in base plate 103, a second nozzle group with three nozzles 112 evenly apart in base plate 103, and a third nozzle group with six nozzles 114 evenly apart in base plate 103.

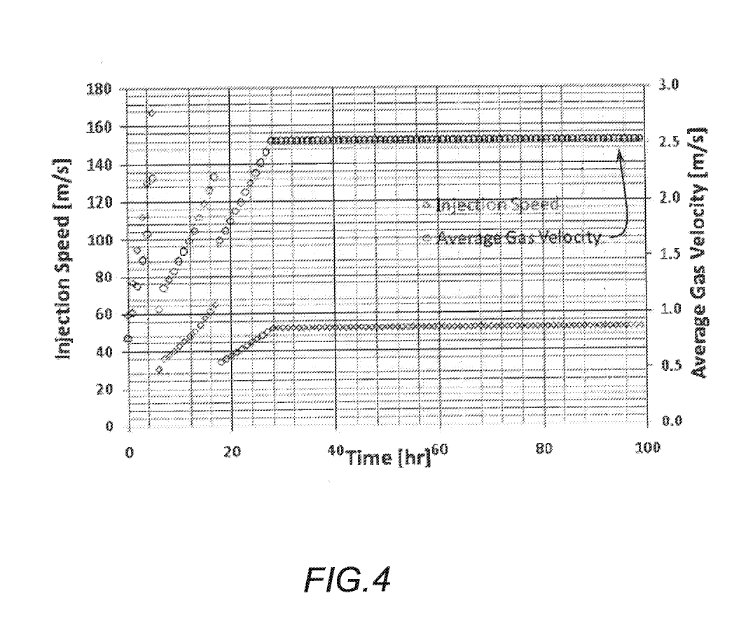

FIG. 4 is a graph showing the injection speed and average gas velocity involving three deposition stages with the first stage involving the first nozzle group (from 0 hr to about 2 hr), the second stage involving the second nozzle group (from about 2 hr to about 18 hr) and the third stage involving the third nozzle group (from about 18 hr).

This example shows that utilizing a plurality of nozzles in several stages can provide a controlled level of average gas velocity while still providing increasing mass flow rates introduced into the reaction chamber, which in turn reduces the potential of undesirable convective heat loss associated with higher flow rates.

Having now described some exemplary embodiments pertinent to one or more aspects of the invention, it should be apparent to those skilled in the art that the foregoing is merely illustrative and not limiting. Numerous modifications and other embodiments are within the scope of one of ordinary skill in the art and are contemplated as falling within the scope of the invention. For example, the controller, when utilized in some configurations of the deposition system of the invention, may incorporate one or more human-machine interfaces or devices to facilitate monitoring the progress of the deposition process. Although many of the examples presented herein involve specific combinations of method acts or system elements, it should be understood that those acts and those elements may be combined in other ways to practice one or more aspects or features of the invention. Thus, for example, rods with layers of differing properties may be created by utilizing permutations of nozzle group sequences, e.g., the first nozzle group followed by the second nozzle group, then the first nozzle group, and then the third nozzle group.

Further, the parameters and configurations described herein are exemplary and that actual parameters and/or configurations will depend on the specific application in which the systems and techniques of the invention are implemented.

As used herein, the term “plurality” refers to two or more items or components. The terms “comprising,” “including,” “carrying,” “having,” “containing,” and “involving,” whether in the written description or the claims, are open-ended terms, i.e., to mean “including but not limited to.” Thus, the use of such terms is meant to encompass the items listed thereafter, and equivalents thereof, as well as additional items. Only the transitional phrases “consisting of” and “consisting essentially of,” are closed or semi-closed transitional phrases, respectively, with respect to the claims. The use of ordinal terms such as “first,” “second,” “third,” and the like in the claims to modify a claim element does not by itself connote any priority, precedence, or order of one claim element over another or the temporal order in which acts of a method are performed, but are used merely as labels to distinguish one element having a certain name from another element having a same name, but for use of the ordinal term.

What is claimed is:

1. A method for making polycrystalline silicon from a gas comprising at least one silicon precursor compound, the method comprising:
establishing a first flow pattern of the gas in a chemical vapor deposition reaction chamber;
promoting reaction of at least a portion of the at least one precursor compound from the gas having the first flow pattern into polycrystalline silicon;
establishing a second flow pattern of the gas in the reaction chamber; and
promoting reaction of at least a portion of the at least one precursor compound from the gas having the second flow pattern into polycrystalline silicon.

2. The method of claim 1, wherein establishing the first flow pattern comprises introducing the gas into the reaction chamber through a first nozzle group.

3. The method of claim 2, wherein the first nozzle group consists of a single nozzle.

4. The method of claim 1, wherein establishing the first flow pattern comprises introducing the gas into the reaction chamber through a first nozzle group and establishing the second flow pattern of the gas in the reaction chamber comprises introducing the gas through a second nozzle group.

5. The method of claim 4, wherein establishing the second flow pattern of the gas in the reaction chamber comprises discontinuing the introduction of the gas through the first nozzle group.

6. The method of claim 4, further comprising establishing a third flow pattern of the gas in the reaction chamber.

7. The method of claim 6, wherein establishing the third flow pattern of the gas in the reaction chamber comprises discontinuing the introduction of the gas through the first nozzle group.

8. The method of claim 6, wherein establishing the third flow pattern of the gas in the reaction chamber comprises discontinuing the introduction of the gas through the second nozzle group.

9. A method for making polycrystalline silicon from a gas comprising a silicon precursor compound in a chemical vapor deposition system, the method comprising:
introducing at least a portion of the gas comprising the polycrystalline silicon precursor compound into a reaction chamber of the chemical vapor deposition system through a first nozzle group;
promoting conversion of at least a portion of the precursor compound into polycrystalline silicon from the at least a portion of the gas introduced into the reaction chamber through the first nozzle group;
introducing at least a portion of the gas into the reaction chamber through a second nozzle group; and
promoting conversion of at least a portion of the precursor compound into polycrystalline silicon from the at least a portion of the gas introduced into the reaction chamber through the second nozzle group.

10. The method of claim 9, wherein the first nozzle group consists of a single nozzle.

11. The method of claim 9, further comprising:
introducing at least a portion of the gas into the reaction chamber through a third nozzle group; and
promoting conversion of at least a portion of the precursor compound into polycrystalline silicon from the at least a portion of the gas introduced into the reaction chamber through the third nozzle group.

12. The method of claim 11, further comprising regulating a flow rate of gas introduced through any of the first nozzle group, the second nozzle group, and the third nozzle group.

13. The method of claim 11, further comprising discontinuing the introduction of the at least a portion of the gas introduced through the first nozzle group.

14. The method of claim 11, further comprising discontinuing the introduction of the at least a portion of the gas introduced through the second nozzle group.

15. The method of claim 11, further comprising:
introducing at least a portion of the gas into the reaction chamber through a fourth nozzle group; and
promoting conversion of at least a portion of the precursor compound into polycrystalline silicon from the at least a portion of the gas introduced into the reaction chamber through the fourth nozzle group.

16. A chemical vapor deposition system, comprising:
a gas source;
a reaction chamber at least partially defined by a base plate and a bell jar;
a first nozzle group disposed in one of the base plate and the bell jar, the first nozzle group fluidly connected to the gas source through a first manifold and a first flow regulator;
a second nozzle group including a plurality of nozzles disposed in one of the base plate and the bell jar, the plurality of nozzles fluidly connected to the gas source through a second manifold and a second flow regulator; and
a controller configured to regulate flow of gas from the gas source through the first nozzle group and flow of gas from the gas source through the second nozzle group.

17. The chemical vapor deposition system of claim 16, further comprising:
a third nozzle group including a plurality of nozzles disposed in one of the base plate and the bell jar, the plurality of nozzles of the third nozzle group fluidly connected to the gas source through a third manifold and a third flow regulator, and
wherein the controller is further configured to regulate flow of the gas from the gas source through the third nozzle group.

18. The chemical vapor deposition system of claim 17, wherein the first nozzle group consists of a single nozzle, the second nozzle group consists of three nozzles, and the third nozzle group consists of six nozzles.

19. The chemical vapor deposition system of claim 16, wherein the first nozzle group consists of a single nozzle and the second nozzle group consists of three nozzles.
